(19) United States
(12) Patent Application Publication
(10) Pub. No.: US 2025/0141440 A1
(43) Pub. Date: May 1, 2025

(54) METHOD AND CIRCUITRY FOR DETERMINING SYSTEM CHARACTERISTICS OF AN ELECTRONIC CIRCUIT

(71) Applicant: Arm Limited, Cambridge (GB)

(72) Inventors: Amit Chhabra, Noida (IN); Rainer Herberholz, Great Abington (GB); Anuj Grover, South Delhi (IN)

(73) Assignee: Arm Limited, Cambridge (GB)

(21) Appl. No.: 18/925,522

(22) Filed: Oct. 24, 2024

(30) Foreign Application Priority Data
Oct. 27, 2023 (IN) 202311073299
Oct. 27, 2023 (IN) 202311073432
Dec. 18, 2023 (IN) 202311086438
Mar. 20, 2024 (GB) 2403978.6
Mar. 20, 2024 (GB) 2403979.4
Mar. 20, 2024 (GB) 2403985.1

(51) Int. Cl. H03K 5/14; H03K 5/135

(52) U.S. Cl. CPC H03K 5/14; H03K 5/135

(57) ABSTRACT

The present techniques relate to a method and circuitry for determining system characteristics of an electronic circuit and there is disclosed a delay monitor circuit to characterise an electronic circuit comprising: a delay line that quantifies the delay within a clock cycle; the delay line comprising a plurality of sampling points therealong; wherein, in a first mode, the delay monitor is configured to capture delay statistics over a given measurement period; and wherein, in a second mode, the delay monitor is configured to capture a measurement value from the plurality of sampling points, wherein the measurement value is indicative of one or more characteristics of the electronic circuit.

### TECHNICAL FIELD

The present techniques relate to a method and circuitry for determining system characteristics of an electronic circuit. In particular, the present techniques relate to determining system characteristics of an electronic circuit in an information processing system.

### BACKGROUND OF THE DISCLOSURE

Some computer circuits (e.g., a central processor unit (CPU) or graphics processor unit (GPU)) may experience performance issues. For example, individual CPUs may exhibit unique characteristics that affect their operation due to hardware inconsistencies.

There is a need for mitigation action to address such performance issues.

### SUMMARY OF THE DISCLOSURE

The present techniques relate to determining system characteristics of an electronic circuit to tackle such performance issues or improve known mitigation techniques.

According to a first approach there is provided a delay monitor circuit to characterise an electronic circuit comprising: a delay line that quantifies the delay within a clock cycle; the delay line comprising a plurality of sampling points therealong; wherein, in a first mode, the delay monitor is configured to capture delay statistics over a given measurement period; and wherein, in a second mode, the delay monitor is configured to capture a measurement value from the plurality of sampling points, wherein the measurement value is indicative of one or more characteristics of the electronic circuit.

According to the first approach, in the second mode, the delay monitor is configured to input a signal transition into the delay line and sample signal values at one or more of the plurality of sampling points to capture a measurement value.

According to the first approach, in the second mode, the delay monitor is to capture the measurement value for a plurality of clock cycles.

According to the first approach, the delay monitor is configured to sample signal values under control of a control clock signal.

According to the first approach, the signal transition is input into the delay line after a predetermined delay.

According to the first approach, the predetermined delay is a number of clock cycles of the control clock signal according to a configurable delay value.

According to the first approach, the configurable delay value is obtained from storage.

According to the first approach, the predetermined delay is the number of clock cycles according to the configurable delay value and a configurable scaling value.

According to the first approach, a further signal transition is transmitted into the delay line after a predetermined delay according to the configurable scaling value; and signal values along the delay line are sampled to generate an indication of a current location of the signal transition.

According to the first approach, the measurement value is captured based on a number of gate stages in the delay line traversed by the signal transition according to the sampled signal values.

According to the first approach, the sampling points are distributed along the delay line to provide a sampling point between each delay element.

According to the first approach, the circuit comprises a coarse delay module and a fine delay module.

According to the first approach, the fine delay module comprises a final delay element traversed by the signal transition before the sampling points are sampled.

According to the first approach, the plurality of clock cycles comprises 8 clock cycles; optionally the plurality of clock cycles comprises 16 or 32 clock cycles.

According to the first approach, the plurality of clock cycles comprises a plurality of successive clock cycles.

According to the first approach, a characteristic of the electronic circuit includes one or more of a voltage response, current response, temporal response, switching threshold, capacitive response or inductive response of a component of the electronic circuit.

According to the first approach, a component of the electronic circuit includes one or more of logic components, transistors, transistor gates, resistors, capacitors and inductors.

According to the first approach, the delay monitor is to provide the one or more measurement values to a component for processing.

According to a further approach there is provided a method of characterising an electronic circuit using a delay monitor comprising: inputting a signal transition through a delay line of the delay monitor, the delay line comprising a plurality of sampling points therealong, where in a first mode the delay monitor is configured to capture delay statistics over a given measurement period; and capturing, in a second mode, a measurement value from the plurality of sampling points, where the one or more measurement value is indicative of one or more system characteristics of the electronic circuit.

According to a further approach of the present techniques, there is provided a monitor circuit for characterising a system, the monitor comprising: a delay line having a plurality of sampling points; wherein, according to a configurable control signal, the monitor is to sample signal values at one or more of the plurality of sampling points and to capture a measurement value according to the sampled signal values; and wherein the configurable control signal defines a rate at which signal values are sampled.

According to the further approach, the configurable control signal comprises a control clock signal.

According to the further approach, configurable control signal defines a rate at which signal values are sampled responsive to a configurable scaling value.

According to the further approach, signal values are sampled after a predetermined delay.

According to the further approach, the predetermined delay is defined responsive to a configurable delay value.

According to the further approach, one or both of the configurable delay value and the configurable scaling value are obtained from storage.

According to the further approach, the predetermined delay is defined responsive to the configurable delay value and the configurable scaling value.

According to the further approach, measurement values are indicative of one or more characteristics of the system.

According to a further approach of the present techniques, there is provided a method of characterising an electronic circuit using a monitor circuit comprising a delay line having a plurality of sampling points, the method comprising: sampling, according to a configurable control signal, signal values at one or more of the plurality of sampling points; and capturing a measurement value according to the sampled signal values; wherein the configurable control signal defines a rate at which signal values are sampled.

According to a further approach of the present techniques, there is provided a delay monitor circuit to characterise an electronic circuit comprising a delay line comprising a plurality of sampling points therealong; wherein, in a first mode, the delay monitor is configured to quantify a delay within a clock cycle; and wherein, in a second mode, the delay monitor is configured to input a signal transition into the delay line and sample signal values at one or more of the plurality of sampling points to capture a measurement value, wherein the measurement value is indicative of one or more characteristics of the electronic circuit.

According to a further approach of the present techniques, there is provided a method of characterising an electronic circuit using a delay monitor, the method comprising: inputting a signal transition through a delay line of the delay monitor, the delay line comprising a plurality of sampling points therealong; and generating one or more measurement values by sampling signal values of the signal transition at one or more of the plurality of sampling points, where the one or more measurement values are indicative of one or more system characteristics of the electronic circuit.

According to a further approach of the present techniques, there is provided an electronic circuit comprising electronic logic components operable to perform the steps of a method according to the above approaches.

According to a further approach of the present techniques, there is provided a processor comprising circuitry according to the above approaches.

According to a further approach of the present techniques, there is provided a system comprising: circuitry according to any one of the above approaches, implemented in at least one packaged chip; at least one system component; and a board, wherein the at least one packaged chip and the at least one system component are assembled on the board.

According to a further approach of the present techniques, there is provided a chip-containing product comprising the system of the above approach assembled on a further board with at least one other product component.

According to a further approach of the present techniques, there is provided a non-transitory computer-readable medium to store computer-readable code for fabrication of circuitry according to one or more of the above approaches.

### BRIEF DESCRIPTION OF DRAWINGS

Implementations of the disclosed technology will now be described, by way of example only, with reference to the accompanying drawings, in which:

FIG. 1A schematically shows a diagram of a delay monitor according to the present techniques;

FIG. 1B schematically shows a diagram of an example delay line of the delay monitor of FIG. 1A;

FIG. 2 schematically shows a flowchart showing a simplified of a method of sampling according to an implementation of the present techniques;

FIG. 3 shows a schematic diagram of waveforms obtained by sampling according to an implementation of present techniques with and without a sampling delay;

FIG. 4 shows a schematic diagram of waveforms obtained by scaled sampling according to an implementation of present techniques with and without a sampling delay; and

FIG. 5 shows a system and a chip-containing product.

### DETAILED DESCRIPTION

Delay monitors are used to quantify, or measure, delay in clock cycles. Delay monitors are used for integration within a system (e.g., CPU, GPU cores) or portion thereof. A delay monitor may sample a logic depth traversed by a signal transition (a signal to be measured) during a clock cycle and report data, such as delay statistics data, to a system control processor (SCP) or other component to process such data responsive to the progress of the signal transition.

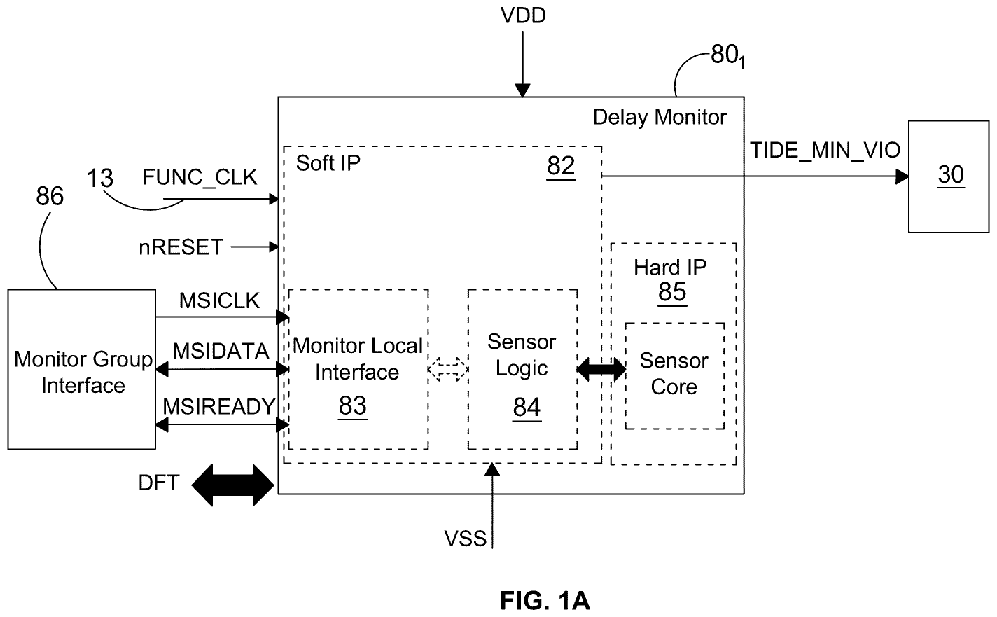

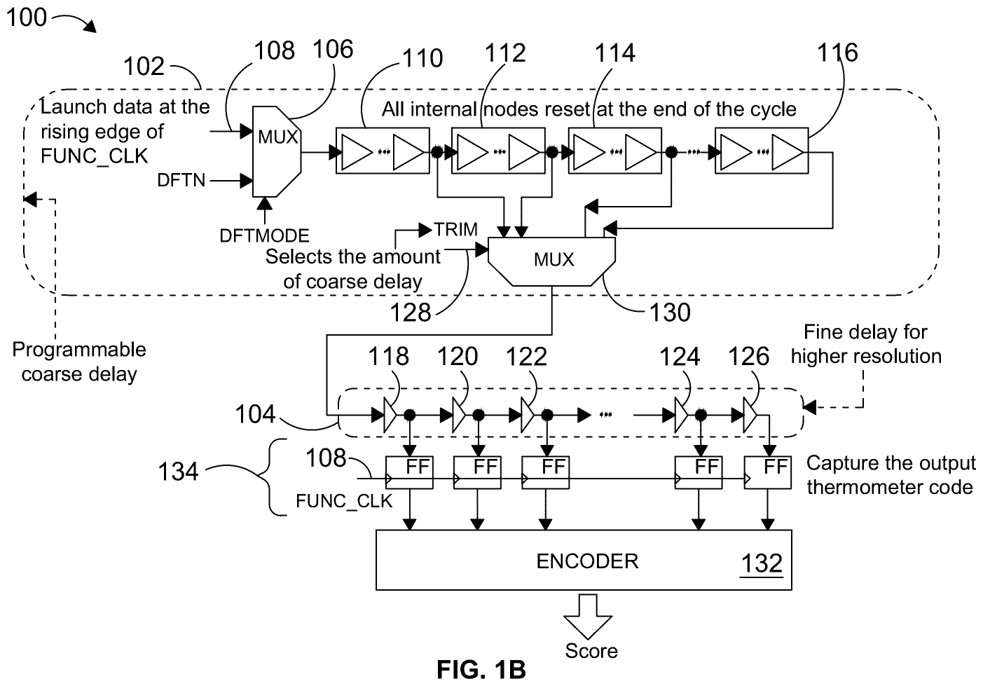

An illustrative example of a delay monitor 801 is schematically shown in the high-level diagram of FIG. 1A, and comprises soft IP, which in the present illustrative example, comprises a local interface 83 and sensor logic 84.

The delay monitor also comprises hard IP 85, which in the present illustrative example comprises a sensor core 85, which may be tied, for example, to the monitored location's (e.g., CPU/GPU) logic voltage supply. An example of the sensor core 85 which may be used in accordance with the present techniques is illustratively shown in FIG. 1B. It will be appreciated that the delay lines in FIG. 1B are only provided as an illustrative example and the claims are not limited to the specific delay lines shown.

The sensor core 85 may comprise one or more delay lines connected to a particular area of the sub-system (e.g., a top metal or bottom metal area) to measure delays in that particular area and capture a measurement value or score (hereafter “measurement value”) which may be processed at the delay monitor or output as statistics data to be processed at another component (hardware and/or software component). An example of the delay lines used by sensor core 85 is depicted in FIG. 1B.

A monitor group interface 86 may provide communications between the local interfaces of the respective delay monitors 801-n and may send/receive signals to/from each of the local interfaces 83. Each of the delay monitors 801-n may be activated independently of each other.

In a first mode of operation, the delay monitor 801-n quantifies a delay within a clock cycle and captures one or more measurement values related to the quantified delay, and may generate one or more alert signals (e.g., violation or non-violation signals) responsive to the one or more measurement values, where the one or more alert signals may be provided to a component (e.g. a state machine, SCP etc.) to take an action in response to the one or more alert signals.

In the first mode of operation to quantify a delay, a measurement value is provided by the output of the encoder 132 where the measurement value corresponds to a count of the number of fine gate stages traversed in the fine delay line during a sampling period, wherein the sampling period corresponds to a predetermined number of clock cycles. The output may be measured every output clock cycle (e.g., FUNC_CLK) of a clock distribution network and averaged over a predetermined number of clock cycles for analysis.

The sensor core of the Hard IP 85 captures this value for each FUNC_CLK cycle when the Delay Monitor 80 is active. This n-bit value is then processed by the sensor logic 84 and statistical data and/or one or more alert signals provided to component(s) as necessary (e.g., to circuitry such as a state machine, SCP or other processor).

The measurement values captured in the first mode can be used to check that the system 1 being monitored (or portions thereof) are operating as expected (e.g., during runtime), and to cause an alert signal when any unexpected or undesired operation is detected.

It will be appreciated that the delay line is only provided as an example of Hard IP 85 to provide a measurement value based on a clock signal. The delay monitor may be used to monitor clock signals in multiple locations on a chip or among circuitry.

Whilst the description above describes the operation of the delay monitor in a first mode, where a sub-system is monitored during operation thereof, in a second mode of operation a delay monitor may be used as a digital oscilloscope primarily to characterise a circuit (e.g., in silicon) post-fabrication, for example as, as a quality control measure or debugging tool. The electronic circuit being characterised may be a Power Delivery Network. The delay monitor may be configured to capture or generate measurement values which are indicative of characteristics of components of an electronic circuit. Characteristics of components of an electronic circuit may include one or more of a voltage response, current response, temporal response, switching threshold, capacitive response or inductive response of a component of an electronic circuit. In particular, the circuit response to a given workload may be monitored when the circuit is connected with capacitance, inductance and the system-on-chip. Further, components of an electronic circuit may include one or more of logic components, transistors, transistor gates, resistors, capacitors and inductors. The measurement values can then be used (e.g., processed at a component (e.g., SCP)) to derive the characteristics and determine whether the characteristics meet one or more defined criteria.

For example, under certain circumstances a delay in clock cycle data may be indicative of transient voltage in a system. By observing a delay in clock cycles for a given system experiencing a given workload at a given temperature, characteristics of the system may be determined.

By using a delay monitor as a digital oscilloscope, a system may be characterised without the need for extra provision of hardware or software components. This may provide system characterisation where otherwise none would be possible. Additionally or alternatively, a system and associated characterisation may be space-efficient through the implementation of a dual-mode delay monitor.

Thus, according to an implementation of present techniques, a delay monitor may be configured to be operate as a digital oscilloscope. Such a delay monitor may operate in oscilloscope mode to input a signal transition into the delay line and sample signal values at one or more of the plurality of sampling points to capture a measurement value wherein the measurement value is indicative of one or more characteristics of the electronic circuit. The delay monitor may operate in oscilloscope mode to capture a measurement value indicative of one or more characteristics of the electronic circuit for each of a plurality of control clock cycles. The number of control clock cycles utilised to capture the measurement value(s) may be limited by the storage (e.g., registers) available to store the measurement values, but may comprise, for example 8, 16, 32, 64 etc. clock cycles. The clock cycles may be successive, i.e., one after another.

In embodiments sampling signal values at every clock cycle may require a significant memory space. Available memory space may limit a duration of a workload measured using the digital oscilloscope, thereby limiting the system observation and effectiveness of characterisation possible. In particular, by sampling at every clock cycle with limited memory availability, a workload duration may be reduced such that higher order harmonic resonances of a system may not be adequately observed in the sampled data. As such, in some scenarios, high-frequency sampling, i.e., sampling at every clock cycle, may be inefficient.

According to an implementation of present techniques, a circuit configured to operate as a digital oscilloscope providing a configurable sample rate is provided. It will be appreciated that the circuit configured to operate as a digital oscilloscope may generate measurement values representative of system characteristics. However, the circuit may output the measurement values for further processing or for display to a user (e.g., as a waveform), rather than processing the measurement values or providing a display to a user itself.

In particular, a configurable number and configurable distribution of clock cycles may be sampled by the digital oscilloscope according to a user's preference. A start of sampling and/or a rate of sampling may be configured to adjust a sampling schedule of the digital oscilloscope. By adjusting a start of sampling, a particular portion of interest of a waveform may be observed. By adjusting a rate of sampling, a view of a waveform provided may be ‘zoomed’ in or out to capture a portion of interest of a waveform in appropriate detail.

The digital oscilloscope may sample signal values and capture measurement values according to a configurable control signal which defines a rate at which the sampling takes place. In some embodiments, the configurable control signal may define a period, frequency, or rate at which a signal transition is transmitted into the delay line, signal values are sampled and measurement values are generated. The configurable control signal may comprise a control clock signal and define a rate at which signal values are sampled responsive to a configurable scaling value and/or a configurable delay value which are described below.

A rate at which signal values are sampled may be defined according to a control clock signal. For example, signal values may be sampled at every second, third or fourth (etc.) rising edge of the control clock signal. The configurable scaling value (DO_ZOOM) (e.g., a programmable or configurable scaling value (e.g., n-bit value) in storage such as a register) may define a number of rising edges of the control clock signal at which signal values are skipped (or not sampled) between sampling events. For example, a configurable scaling value of 1 may indicate that signal values are to be sampled at every other rising edge of the control clock signal. In this way, a rate of sampling is defined by the configurable control signal, subject to the control clock signal, and the configurable scaling value. The configurable scaling value may be zero, in which case signal values may be sampled at every rising edge of the control clock signal.

As described above, by adjusting a rate of sampling, a view of a waveform provided may be ‘zoomed’ in or out to capture a portion of interest of a waveform in appropriate detail. For example, the Delay Monitor may be configured to zoom out to have a relatively quick and coarse sneak into a large duration by setting configurable scaling value DO_ZOOM to any value between 0x1 and 0xF where, as above, the configurable scaling value DO_ZOOM defines the time between capturing measurement or score values. Put another way, the programmable scaling value DO_ZOOM defines the period in-between two successive measurement values. In embodiments the period comprises one or more clock cycles (e.g., FUNC_CLK).

Further, the configurable delay value may define a predetermined delay, following which signal values are sampled according to the configurable control signal. The predetermined delay may elapse between a sample request being received, and sampling beginning according to the configurable control signal. In this way, the configurable delay value may act to delay the configurable control signal.

In this way, by adjusting a start and/or rate of sampling, unnecessary sampling may be reduced. Less memory may be required to store the sampled data. Further, high order harmonic resonances of a system may be observed in a memory-efficient and sampling-efficient manner. Furthermore, system characteristics may be determined efficiently.

It will be understood by one of ordinary skill in the art that the digital oscilloscope comprising configurable sampling according to present techniques may be a delay monitor operating in digital oscilloscope mode or may be any other suitable circuitry.

According to some implementations of present techniques, a delay monitor comprising a plurality of delay elements and a plurality of sampling points distributed along the delay line to provide sampling points between delay elements is operable in a plurality of modes. Such a multi-mode delay monitor comprises a first mode in which the delay monitor is configured to quantify a delay within a clock cycle (e.g., during run-time) and a second mode in which the delay monitor is used to determine system characteristics of an electronic circuit (e.g., post-fabrication). In particular, a delay monitor may be used to measure transient voltage and store the measured voltage profile in memory. In this way, the delay monitor may be used as a digital oscilloscope in the second mode.

When in use as a digital oscilloscope, the delay monitor is configured to transmit a signal transition through the delay line and sample signal values at each of the plurality of sampling points of the delay line for each of a plurality of clock cycles to capture measurement values indicative of system characteristics of an electronic circuit By sampling signal values at each of a plurality of clock cycles, the delay monitor may collect a series of measurement values indicative of a voltage waveform.

Given that the voltage waveform is reproducible for a given system providing an identical workload and temperature, the voltage waveform may provide insight into the system response to a given workload. Accordingly, the delay monitor may be used in digital oscilloscope mode to characterise a system (e.g., electronic circuit).

To improve a utility of the delay monitor in digital oscilloscope mode, a sampling of measurement values may be configurable to provide the insight desired. Accordingly, the start of sampling may be delayed and the sampling rate may be adjusted to improve a characterisation of the system.

FIG. 1B shows a schematic diagram of a delay line 100 according to an implementation of present techniques. The delay line 100 comprises a coarse delay path or module 102 and a fine delay path or module 104. The coarse delay module 102 and the fine delay module 104 each comprise delay elements and sampling points. In the coarse delay module 102, sampling points are distributed between delay element groups 110, 112, 114, 116 to provide sampling points between some delay elements. In the fine delay module 104, sampling points are distributed between individual fine delay elements 118, 120, 122, 124, 126 to provide sampling points between each delay element. In this way, the fine delay module provides high resolution sampling of the delay in the delay line, while the coarse delay line provides low resolution sampling.

In use in the second mode as a digital oscilloscope, a signal transition is transmitted, or launched, from multiplexer 106 at the rising edge of FUNC_CLK 108. The signal transition proceeds along the delay line, traversing a combination of coarse delay element groups 110, 112, 114, 116 and fine delay elements 118, 120,122, 124, 126 according to the configurable TRIM element 128 which acts on multiplexer 130 to determine when the signal transition enters the fine delay module from the coarse delay module. Outputs from sampling points located between fine delay elements 118, 120, 122, 124, 126 are transmitted to the encoder 132 via flip flops 134 under control of the FUNC_CLK signal 108. At a second edge of FUNC_CLK, the number of gates traversed by the signal transition is determined by the encoder 132 based on the outputs from the sampling points of the fine delay module. The encoder 132 outputs a measurement value, or score, according to the logic depth reached by the signal transition during a clock cycle. Once a measurement value is obtained, all internal nodes are reset ready for a subsequent measurement operation.

The measurement value or score may correlate directly with a number of fine gate stages traversed by the signal transition in a clock cycle. The measurement value or score may be measured for all cycles of FUNC_CLK. To act as a digital oscilloscope in the second mode, the delay monitor is configured to provide the measurement value or score for a plurality of FUNC_CLK cycles. The sampling of the measurement value or score may be configured by delaying a start of sampling and/or delaying a sampling interval to provide a desired measurement window. The measurement value or scores thus obtained may be indicative of one or more characteristics. For example, the measurement values may be processed/used (e.g., by a system control processor (SCP) or other processor) to plot a waveform indicative of a voltage waveform over the desired measurement window which can provide insights into system characteristics.

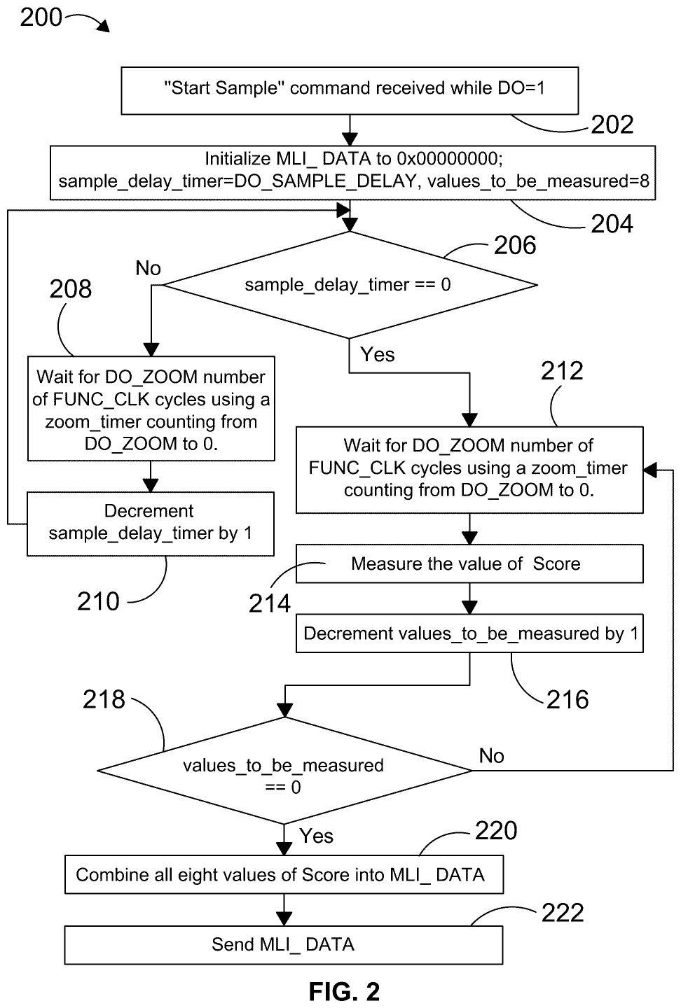

FIG. 2 schematically shows a flowchart 200 showing a simplified of a method of sampling according to an implementation of the present techniques.

According to some implementations of present techniques, an electronic circuit configured to determine system characteristics of another electronic circuit, provides: a delay line, and a configurable delay value. In response to receiving a sample request, a signal transition is transmitted into the delay line after a predetermined delay according to the configurable delay value; and signal values along the delay line are sampled to generate an indication of a current location of the signal transition. In some implementations, a measurement value, or score, indicative of one or more of the characteristics of the system being measured is captured according to the sampled signal values. Accordingly, the configurable delay value is used to delay a start of sampling following receipt of the sample request.

During system characterisation, a sample request “Start Sample”, is received, step 202, while the delay monitor is in the second digital oscilloscope mode (DO=1). The programmable input parameter DO may be n-bit value (e.g., where n=1) which may be stored for example in a register and which may be set, for example, by the SCP. At step 204, the storage (e.g., register(s)) in which the measurement values will eventually be stored, MLI_DATA, is reset to 0, a countdown timer sample_delay_timer is updated with the configurable delay value, DO_SAMPLE_DELAY, and the number of values to be measured, values_to_be_measured is set. In this instance, 8 values are to be measured. In practice, any suitable value may be chosen for values_to_be_measured.

At step 206, the value of sample_delay_timer is polled. If not zero, a pause according to a configurable scaling value occurs, step 208, and sample_delay_timer is decremented by 1, step 210. Steps 206, 208 and 210 define a wait loop during which no samples are taken and that is occupied until the value of sample_delay_timer is zero. When the value of sample_delay_timer reaches zero, a further pause according to the configurable scaling value occurs, step 212. Next, at step 214, the measurement value or score is measured. In other words, at this point a signal transition is transmitted into the delay line and signal values along the delay line are sampled to capture a measurement value or score. The measurement value or score is an indication of a current location of the signal transition after one clock cycle. Accordingly, the configurable scaling value is used to adjust a rate sampling following a start of sampling.

As such, the configurable delay value and configurable scaling value are used to adjust a start and rate of sampling to provide configurable sampling of the waveform to the user. A rate of sampling may be otherwise known as a ‘zoom level’ or similar. The configurable scaling value may be adjusted to adjust a rate of sampling so that samples are taken for example at larger intervals, and this may have the effect of ‘zooming out’ on a particular portion of the waveform so that second, third and higher order harmonic resonances may be observed. Similarly, the configurable scaling value may be adjusted to adjust a rate of sampling so that samples are taken for example at smaller intervals, and this may have the effect of ‘zooming in’ on a particular portion of the waveform so that for example a voltage response in a particular may be observed.

Following the measurement value or score, the variable values_to_be_measured is decremented by 1. At step 218, the value of values_to_be_measured is polled. If not zero, the flow returns to step 212 to repeat steps 212, 214 and 216. In this way, steps 212-218 define a sampling loop that is repeated according to the original value of values_to_be_measured. After a number of measurement values are measured corresponding to the original value of values_to_be_measured, in this case, 8 measurement values or scores, values_to_be_measured is decremented to zero at step 216 and at step 218 the flow exits the sampling loop into step 220. At step 220, all the measurements values, or scores, (DO_SCORE_X) are combined into the register MLI_DATA. Finally, at step 222, MLI_DATA is output, e.g., to a processor unit (e.g., SCP) so the data may be used.

As described above, when operating in the second mode all measurement values are combined in storage, where the storage is depicted as register MLI_DATA on the local interface. In an illustrative example, each measurement value DO_SCORE_X may comprise “n” bits, where n≥1 (e.g., 7-bits) and may be stored in storage (e.g., a register in the local interface). After receiving the “Start Sample” command, the FUNC_CLK in which the measurement value is measured for this n-bit value is:

$$\{ DO\_SAMPLE \_DELAY * ( 1 + DO\_ZOOM ) \} + \{ N * ( 1 + DO\_ZOOM ) \} ; where N = X + 1.$$

In an illustrative embodiment, DO_SCORE_0 captures the first 7-bit measurement value. After receiving the “Start Sample” command, the FUNC_CLK in which the measurement value for this n-bit value is: {DO_SAMPLE_DELAY*(1+DO_ZOOM)}+{N*(1+DO_ZOOM)}, where N=1.

Similarly, DO_SCORE_1 captures the second 7-bit measurement value; DO_SCORE_2 captures the third 7-bit measurement value; DO_SCORE_3 captures the fourth 7-bit measurement value; DO_SCORE_4 captures the fifth 7-bit measurement value; DO_SCORE_5 captures the sixth 7-bit measurement value; DO_SCORE_6 captures the seventh 7-bit measurement value; DO_SCORE_7 captures the eighth 7-bit measurement value. The captured data may then be output from the registers (e.g., in order from DO_SCORE_0 to DO_SCORE_7).

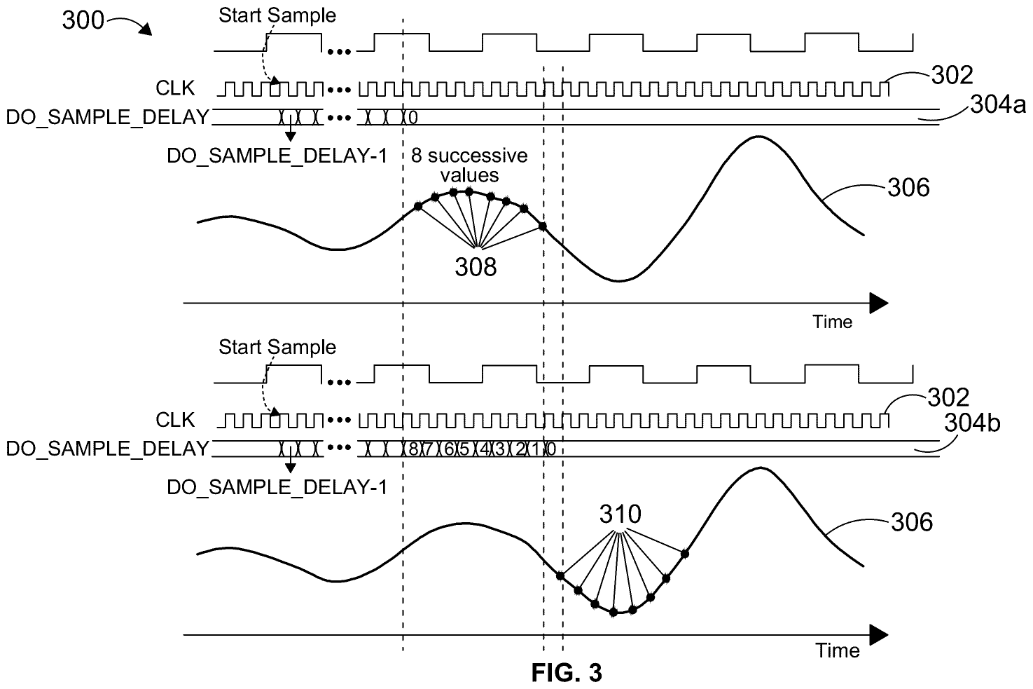

With reference to FIG. 3, a schematic diagram 300 of waveforms obtained by sampling according to an implementation of present techniques with and without a sampling delay is shown. FIG. 3 shows clock, CLK, waveforms 302, sample_delay_timer values 304a, 304b and voltage waveforms 306 for two measurement scenarios. Eight measurement values, or scores, are plotted along each voltage waveform 306. The first of measurement values 308 is plotted one clock cycle after 304a shows a 0 value. Similarly, the first of measurement values 310 is plotted one clock cycle after 304b shows a 0 value.

Measurement values 308 precede measurement values 310 by eight clock cycles. During the eight clock cycles in which measurement values 308 are plotted, the value of sample_delay_timer shown in 304b is decremented from DO_SAMPLE_DELAY to zero. The value of sample_delay_timer 304b starts at 8 and counts down to 0, decrementing once per clock cycle. Accordingly, samples corresponding to measurement values or scores 310 are taken a delay of eight clock cycles after samples corresponding to measurement values or scores 308. Each sample is taken at an interval of one clock cycle. Accordingly, samples are taken for successive clock cycles and the measurement values 308 and 310 plotted relate to successive clock cycles. By setting DO_SAMPLE_DELAY to eight, the measurement values or scores measured may be delayed by eight clock cycles. In this way, the user may capture measurement values or scores relating to a portion of voltage waveform 306 of their choice.

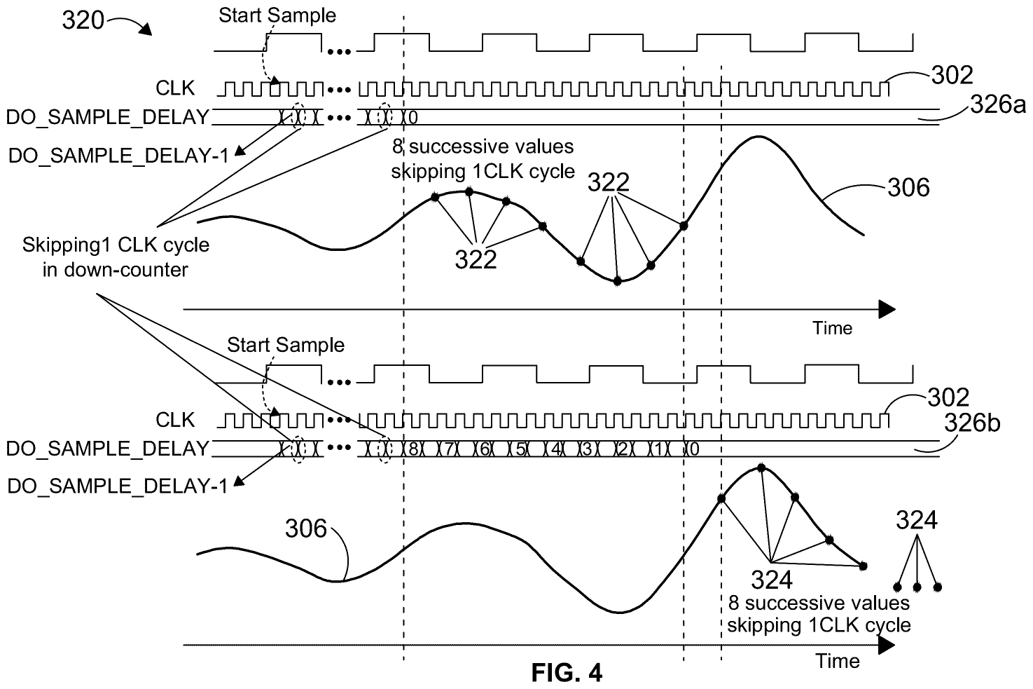

With reference to FIG. 4, a schematic diagram 320 of waveforms obtained by scaled sampling according to an implementation of present techniques with and without a sampling delay is shown. Features of FIG. 4 described with reference to FIG. 3 are given the same reference numerals and are not described in detail again.

FIG. 4 shows an alternative sampling schedule to FIG. 3. FIG. 4 shows clock, CLK, waveforms 302, sample_delay_timer values 326a, 326b and voltage waveforms 306 for two measurement scenarios. In FIG. 4, eight measurement values 322, 324, or scores, are plotted along each voltage waveform 306. The first of measurement values 322 is plotted two clock cycles after 326a shows a 0 value. Similarly, the first of measurement values 324 is plotted two clock cycles after 326b shows a 0 value.

Measurement values 322 precede measurement values 324 by sixteen clock cycles. During the sixteen clock cycles in which measurement values 322 are plotted, the value of sample_delay_timer shown in 326b is decremented from DO_SAMPLE_DELAY to zero. The value of sample_delay_timer 326b starts at 8 and counts down to 0, decrementing once per two clock cycles. Accordingly, samples corresponding to measurement values or scores 324 are taken a delay of sixteen clock cycles after samples corresponding to measurement values or scores 322. Each sample is taken at an interval of two clock cycles. Accordingly, samples are taken for alternate, non-successive, clock cycles and the measurement values 322 and 324 plotted relate to alternate, non-successive, clock cycles.

FIG. 4 shows value of sample_delay_timer counting down to zero more slowly than in FIG. 3, in fact, taking twice as long to be decremented to zero. The progress of sample_delay_timer is influenced by DO_SAMPLE_DELAY and DO_ZOOM, see FIG. 2. The delay in a start of sampling may be defined according to the following equation.

$$DELAY IN SAMPLE START = DO\_SAMPLE \_DELAY * ( 1 + DO\_ZOOM ) .$$

Additionally, the clock cycle for the N^{th} measurement after a delayed start to sampling is defined as:

$$NUMBER OF CLOCK CYCLES = N * ( 1 + DO\_ZOOM )$$

As an illustrative example, the overall desired duration of clock cycles may too large, for instance, millions of FUNC_CLK cycles. Thus DO_ZOOM may be reduced to inspect a duration of interest more closely. As an example, when the CPU CLK frequency is 3.33 GHZ, setting DO_ZOOM to 0xF (where 0xF is the maximum permitted level of DO_ZOOM supported) will allow the Digital Oscilloscope to sample at 208 MHz (=3.33 GHZ/(1+0xF)=3.33 GHZ/16). The number of “Start Sample” commands to cover 1M FUNC_CLK cycles will reduce from 125K (=1M/8) to just 7813 (=125K/16).

In a further embodiment a delay value (MGI_SMP_DLY) may be counted in MSI clock cycles (MSICLK cycles), where the MSI comprises a synchronous unidirectional serial protocol. In the present illustrative example, the MSI Clock is synchronous at the transmitter group interface/local interface and receiver group interface/local interface. In embodiments all signals are sampled on the rising edge of MSICLK.

In operation a user will calculate the time instance at which the measurement values are desired and calculate the delay value (MGI_SMP_DLY) based on the ratio of MSICLK/FUNC_CLK clock frequencies.

In FIG. 3, after measuring values 308, DO_SAMPLE DELAY was set to 8 to capture measurement values 310. DO_ZOOM was set to zero to provide measurement values that are successive, that is to say that they are each separated by one clock cycle. In FIG. 4, DO_ZOOM is set to 1, so that each measurement value is separated by two clock cycles. After measuring values 322 across sixteen clock cycles, DO_SAMPLE DELAY was set to 8 to capture measurement values 324 across the subsequent sixteen clock cycles. The final three values of 324 are not shown on voltage waveform 306 for compactness.

The method and circuit according to the present technology may thus be used in characterisation of systems having dynamic voltage and frequency scaling, and that method may be realised in the form of a non-transitory computer readable medium comprising a structure of data and imperatives operable to cause a device to construct a set of electronic logic components which, when embedded in an electronic device and activated thereon, cause the electronic device to perform the steps of the method of the present technology as described hereinabove.

The present techniques thus provide for configuring a delay monitor to operate as a digital oscilloscope, which can also comprise programmable functionality to zoom in or out to adjust the duration for which the measurement values are obtained. This functionality can be used to capture measurement values indicative of characteristics of a system being measured (e.g., an electronic circuit), where such functionality can be used to characterise the electronic circuit (e.g., to characterise the silicon post-fabrication).

It will be appreciated that the programmable zoom functionality described above is not limited to a delay monitor having a multi-mode operation and may be implemented in, for example, a dedicated oscilloscope. Further, the concept of zoom out can be extended to other forms of digital storage oscilloscope where a measurement is taken periodically and stored in a memory of some description, such as an on-chip SRAM. For this case, given a fixed SRAM size, the zoom out feature can be used to cover a large time interval by compromising on the resolution of measurement data.

As will be clear to one of skill in the art, a hybrid approach may also be taken, in which hardware logic, firmware and/or software may be used in any combination to implement the present technology.

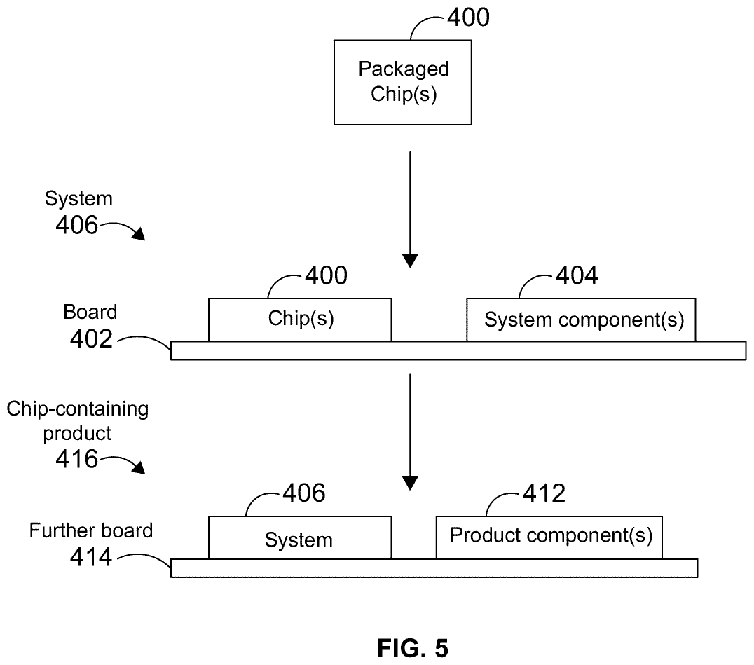

As shown in FIG. 5, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g., made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages) or could be packaged by the semiconductor provider into a multi-chip semiconductor package (e.g., using an interposer, or by using three-dimensional integration to provide a multi-layer chip product comprising two or more vertically stacked integrated circuit layers).

In some examples, a collection of chiplets (i.e., small modular chips with particular functionality) may itself be referred to as a chip. A chiplet may be packaged individually in a semiconductor package and/or together with other chiplets into a multi-chiplet semiconductor package (e.g., using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g., plastic, glass, ceramic, or a flexible substrate material such as paper, plastic, or textile material. The at least one system component 404 comprise one or more external components which are not part of the one or more packaged chip(s) 400. For example, the at least one system component 404 could include, for example, any one or more of the following: another packaged chip (e.g., provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g., a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present techniques may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying present techniques. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying present techniques. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative implementations of the present techniques have been described in detail herein with reference to the accompanying drawings, it is to be understood that the present techniques are not limited to those precise implementations, and that various changes and modifications can be effected therein by one skilled in the art without departing from the scope of the present techniques as defined by the appended claims.

1. A delay monitor circuit to characterise an electronic circuit comprising:
a delay line that quantifies the delay within a clock cycle; the delay line comprising a plurality of sampling points therealong;
wherein, in a first mode, the delay monitor is configured to capture delay statistics over a given measurement period; and
wherein, in a second mode, the delay monitor is configured to capture a measurement value from the plurality of sampling points, wherein the measurement value is indicative of one or more characteristics of the electronic circuit.

2. The circuit according to claim 1, where in the second mode the delay monitor is configured to input a signal transition into the delay line and sample signal values at one or more of the plurality of sampling points to capture a measurement value.

3. The circuit according to claim 1, where in the second mode the delay monitor is to capture the measurement value for a plurality of clock cycles.

4. The circuit according to claim 1, wherein the delay monitor is configured to sample signal values under control of a control clock signal.

5. The circuit according to claim 1, wherein the signal transition is input into the delay line after a predetermined delay.

6. The circuit according to claim 1, wherein the predetermined delay is a number of clock cycles of the control clock signal according to a configurable delay value.

7. The circuit according to claim 6, wherein the configurable delay value is obtained from storage.

8. The circuit according to claim 6, wherein the predetermined delay is the number of clock cycles according to the configurable delay value and a configurable scaling value.

9. The circuit according to claim 1, wherein a characteristic of the electronic circuit includes one or more of a voltage response, current response, temporal response, switching threshold, capacitive response or inductive response of a component of the electronic circuit.

10. A method of characterising an electronic circuit using a delay monitor:
inputting a signal transition through a delay line of the delay monitor, the delay line comprising a plurality of sampling points therealong, where in a first mode the delay monitor is configured to capture delay statistics over a given measurement period; and
capturing, in a second mode, a measurement value from the plurality of sampling points, where the one or more measurement value is indicative of one or more system characteristics of the electronic circuit.

11. A monitor circuit for characterising a system, the monitor comprising:
a delay line having a plurality of sampling points;
wherein, according to a configurable control signal, the monitor is to sample signal values at one or more of the plurality of sampling points and to capture a measurement value according to the sampled signal values; and
wherein the configurable control signal defines a rate at which signal values are sampled.

12. The circuit according to claim 11, where the configurable control signal comprises a control clock signal.

13. The circuit according to claim 11, wherein configurable control signal defines a rate at which signal values are sampled responsive to a configurable scaling value.

14. The circuit according to claim 11, wherein signal values are sampled after a predetermined delay.

15. An electronic circuit comprising electronic logic components operable to perform the steps of the method according to claim 10.

16. A processor comprising circuitry according to claim 1.

17. The processor of claim 16 comprising a central processor unit or a graphics processor unit.

18. A system comprising:
circuitry according to claim 1, implemented in at least one packaged chip;
at least one system component; and
a board,
wherein the at least one packaged chip and the at least one system component are assembled on the board.

19. A chip-containing product comprising the system of claim 18 assembled on a further board with at least one other product component.

20. A non-transitory computer-readable medium to store computer-readable code for fabrication of circuitry according to claim 1.
